(19) United States
(12) Patent Application Publication
(10) Pub. No.: US 2006/0172527 A1
(43) Pub. Date: Aug. 3, 2006

(54) Method for forming a defined recess in a damascene structure using a CMP process and a damascene structure

(76) Inventors: Gerd Marxsen, Radebeul (DE); Frank Mauersberger, Radebeul (DE); Rico Hueselitz, Goeda (DE)

Correspondence Address: WILLIAMS, MORGAN & AMERSON, 10333 RICHMOND, SUITE 1100, HOUSTON, TX, 77042, US

(21) Appl. No.: 11/198,037

(22) Filed: Aug. 5, 2005

(30) Foreign Application Priority Data
Jan. 31, 2005 (DE) 10 2005 004 384.4

(51) Int. Cl. H01L 21/4763; H01L 21/461

(52) U.S. Cl. 438/633; 438/692; 438/626; 438/629

(57) ABSTRACT

The present invention provides a technique that enables the formation of a recessed upper surface of an interconnect line to form an inlaid barrier cap layer on top of an inter-connect line to exhibit improved characteristics with respect to electromigration, electrical conductivity, device reliability and performance. The recessed upper surface of the inter-connect line is formed by an accordingly adapted CMP process that allows removing the metal of an upper portion of the interconnect line, while neighboring elevated barrier layer regions are substantially not affected.

### BACKGROUND OF THE INVENTION

1. Field of the Invention

Generally, the present invention relates to the formation of integrated circuits, and, more particularly, to the formation of metallization layers including highly conductive metals, such as copper, embedded into dielectric materials.

2. Description of the Related Art

In modern integrated circuits, minimum feature sizes, such as the channel length of field effect transistors, have reached the deep sub-micron range, thereby steadily increasing performance of these circuits in terms of speed and/or power consumption. As the size of the individual circuit elements is significantly reduced, thereby improving, for example, the switching speed of the transistor elements, the available floor space for interconnect lines electrically connecting the individual circuit elements is also decreased. Consequently, the dimensions of these interconnect lines have to be reduced to compensate for a reduced amount of available floor space and for an increased number of circuit elements provided per chip. In integrated circuits having minimum dimensions of approximately 100 nm and less, a limiting factor of device performance is the signal propagation delay caused by the switching speed of the transistor elements. As the channel length of these transistor elements is less than 100 nm, it turns out, however, that the signal propagation delay is no longer limited by the field effect transistors, but is limited, owing to the increased circuit density, by the close proximity of the interconnect lines, since the line-to-line capacitance is increased in combination with a reduced conductivity of the lines due to their reduced cross-sectional area that is caused by the reduced available floor space. The parasitic RC time constants therefore require the introduction of a new type of material for forming the metallization layer.

Traditionally, metallization layers are formed by a dielectric layer stack including, for example, silicon dioxide and/or silicon nitride with aluminum as the typical metal. Since aluminum exhibits a higher electrical resistance and significant electromigration at higher current densities than may be necessary in integrated circuits having extremely scaled feature sizes, aluminum is being replaced by copper, which has a significantly lower electrical resistance and a higher resistivity against electromigration.

The introduction of copper, however, entails a plurality of issues to be dealt with. For example, copper may not be deposited in higher amounts in an efficient manner by established deposition methods, such as chemical and physical vapor deposition. Moreover, copper may not efficiently be patterned by well-established anisotropic etch processes and therefore the so-called damascene technique is employed in forming metallization layers including copper lines. Typically, in the damascene technique, the dielectric layer is deposited and then patterned with trenches and vias that are subsequently filled with copper by plating methods, such as electroplating or electroless plating.

A further issue with the copper technology is the ability of copper to readily diffuse in silicon dioxide. Therefore, copper diffusion may negatively affect device performance, or may even lead to a complete failure of the device. It is therefore necessary to provide a diffusion barrier layer between the copper surfaces and the neighboring materials to substantially prevent copper from migrating to sensitive device regions. Thereby, the diffusion barrier layer may also serve to improve adhesion and impart enhanced mechanical stability to the structure. Typically, in the damascene technique, conductive materials, such as, for example, tantalum and tantalum nitride, are deposited within the trenches and vias to form a thin layer or a layer stack providing the required barrier characteristic. Electrically conductive barrier layers on the one hand contribute to the conductivity of the formed interconnect lines but need to be removed from the intermetal dielectric to provide electrically insulated interconnect lines.

Typically, the barrier layer is removed by chemical mechanical polishing (CMP) after a further CMP step is employed to remove excess copper that is formed during the copper plating process in order to reliably fill the trenches and vias. Typical barrier materials, such as tantalum and tantalum nitride, exhibit a significantly higher hardness than copper so that, at least at a last step of the CMP process, respective process parameters are selected to obtain a sufficiently high removal rate, thereby, however, jeopardizing the copper interconnect lines and the underlying dielectric layer due to potential dishing and erosion, in particular when “soft” low-k materials are employed. Since a certain degree of over-polish is required to reliably insulate the individual trenches and lines from each other, a significant over-polish of the copper may occur, especially when the removal rate varies across the substrate surface. The final trenches and vias may then exhibit an undesired resistance variation due to fluctuations in their cross-sectional areas, thereby requiring that the process margins be set correspondingly wider.

Silicon nitride is known as a further effective copper diffusion barrier, and is thus often used as a dielectric barrier material separating the upper copper surface from an inter-layer dielectric, such as silicon dioxide. As previously noted, the device performance of extremely scaled integrated circuits is substantially limited by the parasitic capacitances of adjacent interconnect lines, which may be reduced by decreasing the resistivity thereof and by decreasing the capacitive coupling in that the overall dielectric constant of the dielectric layer is maintained as low as possible. Since silicon nitride has a relatively high dielectric constant k of approximately 7 compared to silicon dioxide (k≈4) or other silicon dioxide based low k dielectric layers (k<4), frequently barrier layers on the basis of silicon carbide are used. Moreover, silicon carbide may provide an enhanced interface bonding for low-k materials compared to silicon nitride. In state of the art semiconductor devices, however, even the lower permittivity of silicon carbide (k≈5) may adversely affect the overall permittivity of the resulting dielectric layer stack.

Although copper exhibits superior characteristics with respect to resistance to electromigration compared to, for example, aluminum, the ongoing shrinkage of feature sizes, however, leads to a further reduction of the size of copper lines and thus to increased current densities in these lines, thereby causing a non-acceptable degree of electromigration despite the superior characteristics of copper. Electromigration is a diffusion phenomenon occurring under the influence of an electric field, which leads to a metal diffusion in the direction of the moving charge carriers, thereby finally producing voids in the metal lines that may cause device failure. In the case of copper, it has been confirmed that these voids may typically originate at the copper/diffusion barrier interface, in particular, at the upper interface with the dielectric sin-, or sic-barrier-layer, and represent one of the most dominant diffusion paths in copper metallization structures. It is therefore of great importance to produce high quality interfaces between the copper and the diffusion barrier, such as the silicon nitride layer or the silicon carbide layer, to reduce the electromigration to an acceptable degree.

The upper copper/diffusion barrier interface may be adversely affected by mechanical stress. Mechanical stress may, for instance, be introduced thermally due to a mismatch of thermal expansion coefficients of the employed materials, or mechanically, for instance, in a subsequently performed CMP step. Thus, the upper barrier layer may be deposited on a recessed upper surface of a copper interconnect line to provide the improved mechanical characteristics of “inlaid” structures and to reduce formation of tiny vacancies which may adversely affect the electromigration behavior at the upper copper/diffusion barrier interface.

The recessed upper surface of the copper interconnect is typically formed by a separate wet or dry copper etch process that, however, is difficult to control since the etch process needs to be precisely stopped within the bulk copper layer to form a recess with a desired depth of a few nanometers. Furthermore, the copper grain structure may affect the uniformity of the etch process since the etch rate at the grain boundary may significantly differ from the etch rate in the copper grains. Thus, the etch process may provide a rather rough recessed surface and may impair the benefit from an inlaid upper barrier layer to the electromigration behavior. In adverse cases, the etch process may even damage the copper interconnect line and thus affect the reliability of a semiconductor device comprising the copper interconnect line.

In addition, irrespective of the barrier material used, significant electromigration may be observed in modern integrated circuits, wherein this effect is further enhanced in the presence of elevated temperatures, mechanical stress and the like, which represent typical operating conditions of modern integrated circuits. Thus, further device scaling may result in reduced device performance or in premature device failure owing to increased metal diffusion along the interface between the barrier layer and the metal line.

In view of the problems with respect to device reliability, parasitic RC time constants and electromigration of metals, such as copper, at interfaces to an overlying surface of a barrier layer, an improved technique is required that may eliminate or at least reduce some of the issues identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention relates to a technique to improve the reliability of interconnects, reduce the parasitic RC time constants, and to effectively reduce the diffusion activity of a metal line at an interface to a cap layer, thereby significantly reducing the metal's tendency for electromigration during increased current densities within the metal line. To this end, the recessed upper surface of the copper interconnect structure is formed by a chemical mechanical polishing process that may provide an improved surface smoothness and depth uniformity of the recessed upper surface of an interconnect line.

According to one illustrative embodiment of the present invention, a method comprises forming a dielectric layer above a substrate and forming a metal region in the dielectric layer, the metal region having an exposed surface. The method further comprises adjusting chemical mechanical polishing process parameters for polishing of the exposed surface, and performing chemical mechanical polishing on the exposed surface with the parameters to intentionally form a recessed surface of the metal region.

According to a further illustrative embodiment of the present invention, a damascene structure comprises a dielectric layer formed above a substrate and a metal region formed in the dielectric layer. The damascene structure further comprises an electrically conductive barrier cap region formed above the metal region.

According to still a further illustrative embodiment of the present invention, a damascene structure comprises a dielectric layer formed above a substrate, a metal region formed in the dielectric layer and a barrier cap region located above the metal region in the dielectric layer.

### BRIEF DESCRIPTION OF THE DRAWINGS

The invention may be understood by reference to the following description taken in conjunction with the accompanying drawings, in which like reference numerals identify like elements, and in which:

FIG. 1 shows a sketch of a CMP unit appropriate for carrying out the present invention;

FIG. 2 schematically depicts a CMP station in a simplified manner which is appropriate for carrying out embodiments of the present invention;

FIGS. 3a-3e schematically show cross-sectional views of a damascene structure during various stages of forming a metal line according to illustrative embodiments of the present invention;

FIGS. 4a-4c schematically show cross-sectional views of a damascene structure during various stages of forming a metal line with an “inlaid” barrier cap layer according to illustrative embodiments of the present invention; and

FIGS. 5a-5b schematically show cross-sectional views of a damascene structure in accordance with further illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

It should be noted that the present invention is particularly advantageous for the formation of sophisticated integrated circuits having copper lines in respective metallization layers, wherein lateral dimensions of the metal lines may be on the order of magnitude of 130 nm or even less, since then the required current densities in these copper lines may result in an increased electromigration of copper, thereby resulting in premature device failure, or in a reduced device performance. Hence, the present invention has the potential for further device scaling of copper-based semiconductor devices, but may also be applied to semiconductor devices of greater lateral dimensions as specified above, thereby contributing to an enhanced reliability of such semiconductor devices. Moreover, the principles of the present invention may also be advantageously applied in combination with other metals considered appropriate for the formation of metal lines in semiconductor devices. For instance, the present invention may be advantageously used with copper alloys, aluminum and the like. It should therefore be appreciated that the present invention should not be considered as being restricted to any device dimensions and materials unless such restrictions are explicitly referred to in the appended claims.

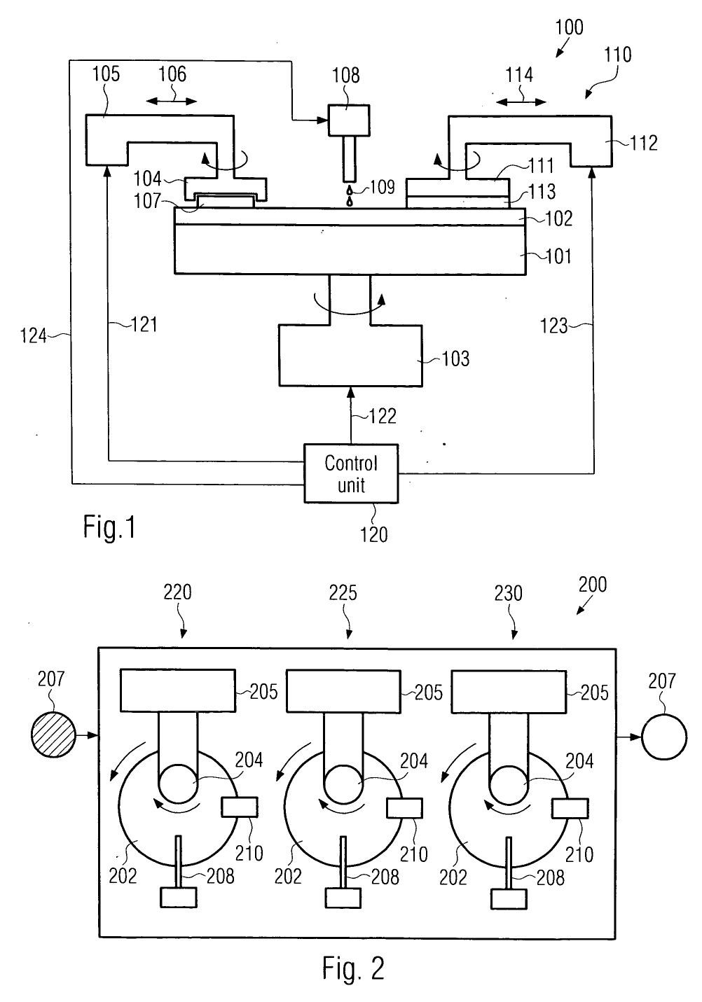

With reference to FIGS. 1, 2, 3a-3e, 4a-4c and 5a-5b, further illustrative embodiments of the present invention will now be described in more detail. FIG. 1 schematically represents a CMP unit 100 that may be employed to carry out a method in accordance with the present invention which is based on a CMP process. The CMP unit 100 comprises a platen 101, on which a polishing pad 102 is mounted. The platen 101 is rotatably attached to a drive assembly 103 that is configured to rotate the platen 101 at any desired revolution between a range of zero to some hundred revolutions per minute. A polishing head 104 is coupled to a drive assembly 105, which is adapted to rotate the polishing head 104 and to move it radially with respect to the platen 101, as is indicated by arrow 106.

Furthermore, the drive assembly 105 may be configured to move the polishing head 104 in any desired manner necessary to load and unload a substrate 107, which is received and held in place by the polishing head 104. A slurry supply 108 is provided and positioned such that a slurry 109 may appropriately be supplied to the polishing pad 102. The amount of a complexing agent contained in the slurry to support the formation of chemically active compounds may be controlled. The corresponding control means, that may be a valve controlling the flow of the complexing agent, may be disposed at the slurry supply 108 or may be located at a separate slurry conditioning/supply unit (not shown).

The CMP unit 100 further comprises a conditioning system 110 which will also be referred to hereinafter as pad conditioner 110 including a head 111, attached to which is a conditioning member 113 including a conditioning surface comprised of an appropriate material such as diamond, having a specified texture designed to control a conditioning effect on the polishing pad 102. The head 111 is connected to a drive assembly 112, which, in turn, is configured to rotate the head 111 and move it radially with respect to the platen 101, as is indicated by the arrow 114. Moreover, the drive assembly 112 may be configured to provide the head 111 with any movability required for yielding the appropriate conditioning effect.

The CMP unit 100 further comprises a control unit 120, which is operatively connected to the drive assemblies 103, 105 and 112 and to the slurry supply 108 to control slurry provision and in particular to control the amount of complexing agent contained in the slurry. The control unit 120 may be comprised of two or more subunits that may communicate with appropriate communication networks, such as cable connections, wireless networks and the like. For instance, the control unit 120 may comprise a sub-control unit as is provided in conventional CMP units to appropriately provide control signals 121, 122, 123 and 124 to the drive assemblies 105, 103, 112 and to the slurry supply 108, respectively, to coordinate the movement of the polishing head 104, the polishing pad 102 and the pad conditioner 110 and to control the amount of complexing agent contained in the slurry 109. The control signals 121, 122 and 123 may represent any suitable signal form to instruct the corresponding drive assemblies to operate at the required rotational and/or translatory speeds.

During the operation of the CMP unit 100, the substrate 107 may be loaded onto the polishing head 104, which may have been appropriately positioned to receive the substrate 107 and convey it to the polishing pad 102. It should be noted that the polishing head 104 typically comprises a plurality of gas lines supplying vacuum and/or gases to the polishing head 104 to fix the substrate 107 and to provide a specified down force during the relative motion between the substrate 107 and the polishing pad 102.

The various functions required for properly operating the polishing head 104 may also be controlled by the control unit 120. The amount of complexing agent contained in the slurry 109 is adjusted in accordance with the performed polishing process. The slurry supply 108 is actuated, for example by the control unit 120, to supply the slurry 109 with a controlled amount of complexing agent. The slurry is distributed across the polishing pad 102 upon rotating the platen 101 and the polishing head 104. The control signals 121 and 122 supplied to the drive assemblies 105 and 103, respectively, effect a specified relative motion between the substrate 107 and the polishing pad 102 to achieve a desired removal behavior, which depends, as previously explained, among others on the characteristics of the substrate 107, the construction and current status of the polishing pad 102, the composition of slurry 109 used, the relative speed between the polishing head and the polishing pad 102 and on the down force applied to the substrate 107. Prior to and/or during the polishing of the substrate 107, the conditioning member 113 is brought into contact with the polishing pad 102 to rework the surface of the polishing pad 102. To this end, the head 111 is rotated and/or swept across the polishing pad 102, wherein, for example, the control unit 120 provides the control signal 123 such that a substantially constant speed, for example, a rotational speed, is maintained during the conditioning process. Different CMP processes may be performed sequentially on a single CMP unit 100 or may preferably be carried out on a CMP station that may comprise several CMP units to perform different CMP processes requiring, for example, different polishing pads and/or different slurry compositions, on different CMP units.

FIG. 2 schematically shows, in a simplified manner, a CMP station 200 that may be appropriate for carrying out a sequence of CMP processes according to the present invention. The CMP station 200 comprises a plurality of CMP units 220, 225 and 230 that may be operated separately from each other. At least one of the CMP units 220, 225 and 230 comprises the control capabilities of the CMP unit 100 of FIG. 1. Each of the CMP units 220, 225 and 230 comprises a polishing head 204 including an appropriate drive means 205. The polishing heads 204 are adapted to receive, hold in position and convey a substrate 207 to be polished. Moreover, the CMP units 220, 225 and 230 each include a polishing platen with a polishing pad 202 provided thereon and a pad conditioner 210 as well as a slurry supply 208. It should be noted that the CMP station 200 is quite complex and usually comprises various drive means for driving the polishing pads 202 relative to the polishing heads 204 as indicated by the corresponding arrows. Moreover, the polishing heads 204 are typically configured to allow the application of a specified down force to a substrate attached thereto. Moreover, the polishing head and the driving means associated therewith are configured to provide substrate transportation from one CMP unit to another so that a substrate may sequentially be processed by the CMP units 220, 225 and 230 of the CMP station 200.

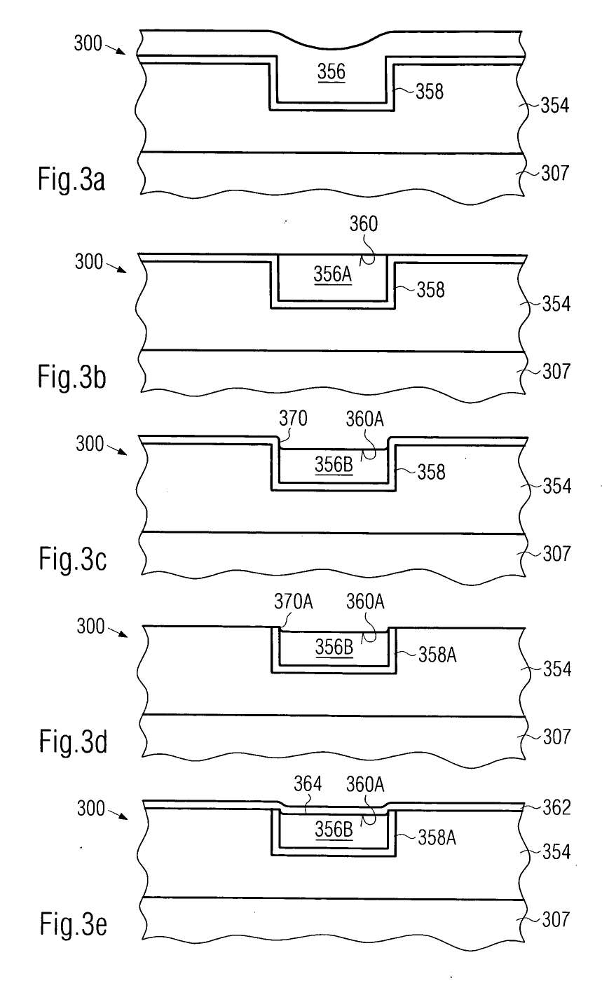

In operation, a substrate 207 including copper-containing surface portions that have to be polished, for example, a damascene structure as described with reference to FIG. 3a, is supplied to the CMP unit 220. Process parameters, such as the speed of the relative motion between the polishing pad 202 and the polishing head 204, the applied down force, the type of slurry supplied by the slurry supply 208, polish time and the like, are adjusted in conformity with the specified process recipe. Typically at least three polishing steps are carried out for removing excess material, recessing the upper surface of an interconnect line as will be described in more detail with reference to FIG. 3a, and for removing a barrier layer for forming a damascene structure of the present invention, wherein at least the CMP step for forming the recessed surface is performed on the CMP unit having the control capability of the CMP unit 100 of FIG. 1. After completion of the first phase of the CMP process, the substrate 207 is conveyed to the CMP unit 225 to be subjected to a second polishing step in accordance with the specified process recipe. After completion of the second phase of the CMP process, the substrate 207 is conveyed to the CMP unit 230 to be subjected to a third polishing step in accordance with the specified process recipe. If the step carried out on the process unit 230 is the last process in the polish sequence, typically the substrate 207 is subjected to a rinse treatment employing, for instance, de-ionized water to remove particles and/or additives from the substrate surface. After the CMP sequence, copper-based metal regions exhibit the recessed surface as set forth with respect to FIGS. 3a-3e.

In FIG. 3a, a damascene structure 300 comprises a substrate 307, which may include semiconductive material provided in or on the substrate 307 and may comprise any appropriate semiconductor element or semiconductor compound usable for the production of integrated circuits. Since the vast majority of the integrated circuits are fabricated as silicon-based devices, the substrate 307 may represent a silicon substrate or a silicon-on-insulator (SOI) substrate having formed thereon a plurality of circuit elements that may be connected to each other in conformity with the circuit design by a metal line to be formed. For convenience, corresponding circuit elements are not shown in the substrate 307. A dielectric layer 354, which may be comprised of any appropriate dielectric material, such as silicon dioxide and/or silicon nitride, or a low-k dielectric material, such as SiCOH, polymers and the like, is formed above the substrate 307. The dielectric layer 354 contains an opening that is filled with a highly conductive material of a deposited metal layer 356. A barrier layer 358 is disposed between the metal layer 356 and the dielectric layer 354.

A typical process flow for forming the damascene structure 300 as shown in FIG. 3a may comprise the following processes. After providing the substrate 307, which may include the formation of various circuit elements in conformity with well-established manufacturing processes, the dielectric layer 354 is formed above the substrate 307 by well-established processes that are selected in accordance with the specifics of the dielectric layer 354. For instance; the dielectric layer 354 may be comprised of a silicon dioxide/silicon nitride layer stack with a thin silicon nitride layer (not shown) followed by a thick silicon dioxide layer, wherein these layers may be deposited by well-established plasma enhanced chemical vapor deposition (PECVD) techniques with a required thickness, wherein the silicon nitride layer may serve as an etch stop layer in a subsequent patterning process. In other embodiments, the dielectric layer 354 may be formed by spin-on techniques when the dielectric layer 354 is substantially comprised of a low-k polymer material.

Thereafter, the opening in the dielectric layer 354 is formed by advanced photolithography and anisotropic etch techniques, wherein, as previously explained, a corresponding etch stop layer may assist in reliably stopping the anisotropic etch process on or in the etch stop layer that may subsequently be opened at dedicated regions to form connections to circuit elements contained in the substrate 307.

The sidewalls and the bottom of the opening may be covered by a conductive barrier layer 358 to substantially prevent the diffusion of metal into the surrounding dielectric of the layer 354 and/or to impart the required adhesion strength to the metal layer 356. The conductive barrier layer 358 may be provided in combination with copper or copper-based alloys, since copper may readily diffuse in a plurality of dielectric materials, such as silicon dioxide and low-k dielectrics. The conductive barrier layer 358 may be comprised of two or more sub-layers to meet the requirements with respect to diffusion mitigating and adhesion characteristics. The conductive barrier layer 358 may be deposited by advanced physical vapor deposition (PVD), chemical vapor deposition, atomic layer deposition, and the like. For instance, when copper is used, a tantalum/tantalum bi-layer may be formed with a thickness in the range of approximately 5-50 nm.

The layer 356 of highly conductive material may comprise copper, copper alloys, aluminum, aluminum alloys, or any other metal that is considered appropriate for providing the required conductivity. In particular embodiments, the metal layer 356 is substantially comprised of copper, as copper is presently considered the most promising candidate for the formation of highly conductive metallization layers.

Depending on the deposition process for depositing the metal layer 356, a seed layer (not shown) may be deposited on the conductive barrier layer 358 to promote metal deposition in a subsequent plating process. For instance, if copper is to be deposited by electroplating, a thin copper seed layer may be deposited by sputter deposition. Thereafter, the metal layer 356, for instance comprised of copper, copper alloys and the like, may be deposited, for instance by electroplating, electroless plating and the like, to reliably fill the opening in the dielectric layer 354.

Typically, during the deposition process, excess metal has to be deposited to reliably fill the opening, wherein the metal residues have then to be removed, for instance, by chemical mechanical polishing (CMP) and/or electrochemical etching and/or chemical etching.

FIG. 3b shows the damascene structure 300 after removing the excess metal. Corresponding processes for removing excess metal from the dielectric layer 354 are well established in the art. By removing the excess metal, the metal region 356a is formed, wherein an upper surface 360 thereof is exposed by the removal process.

In the case of applying a CMP removal process, for instance, a CMP unit 100 as described with respect to FIG. 1 may be used. If the CMP process is performed on a CMP system 200 as described with respect to FIG. 2, the process may, for instance, be carried out on the CMP unit 220. Corresponding CMP recipes defining a corresponding set of parameters, in particular for CMP of copper, are well known. The recipes establish at least the appropriate parameters for a down force exerted to the substrate 307, the relative speed between the substrate 307 and a polishing pad 102, an amount of complexing agent contained in the supplied slurry and the hardness of the polishing pad 102. Furthermore, parameters for controlling the pad conditioner 110, for example, the conditioning interval, the conditioner (rotation- and/or translation-)speed, and/or the conditioner texture may be defined. For copper lines, the barrier layer 358 may serve as a CMP stop layer since the barrier-layer 358, for example, when tantalum and tantalum nitride are employed, are harder than the copper material and may substantially resist the copper CMP.

FIG. 3c depicts the damascene structure 300 after a specifically designed CMP process for recessing the upper surface 360 of the metal region 356a thereby forming a metal region 356b having a recessed upper surface 360a. An upper portion 370 of the sidewalls of the opening in the dielectric layer 354 that may be covered by the barrier layer 358 is exposed.

For recessing the entire surface 360, a CMP unit 100 as described with respect to FIG. 1 may be used that may be part of a CMP system 200 as described with respect to FIG. 2. The CMP process may, for instance, be carried out on the CMP unit 225 after the substrate is conveyed from unit 220 to unit 225. The CMP recipe for recessing the surface 360 after removal of the excess metal differs from the conventional CMP recipes for excess copper removal in that the down force exerted to the substrate 307 is increased, and/or the relative speed between the substrate 307 and a polishing pad 102 is reduced, and/or the amount of complexing agent contained in the supplied slurry is increased, and/or a softer polishing pad 102 is employed, and/or the polishing pad 102 is more embossed, and/or the pad conditioning effect is increased, for example, by employing a coarser texture of the conditioning surface. In illustrative embodiments, the down force may be in the range of approximately 5-7 psi, the relative speed may be less than approximately 50 m/min, the amount of the complexing agent may be increased by a factor in the range of 2 to 10, and an embossed Politex pad may be employed. In a specific embodiment, the amount of the complexing agent is increased by a factor of approximately 4. The polishing time is in the range of approximately 10-30 seconds.

When the CMP process for recessing the surface 360 is performed prior to barrier removal, the barrier layer 358 may again serve as a CMP stop layer. Exposed corners of the barrier layer 358 may be rounded during this process, but, due to the superior hardness of the barrier material, the barrier layer 358 may substantially resist the CMP process without deteriorating the dielectric material. As a result, the recessed surface 360a of the metal region 356b is formed, wherein the recessed surface is substantially smooth and substantially flat due to the accordingly adjusted CMP parameters.

The CMP process for removing the excess copper, as described with respect to FIG. 3b, and the CMP process for forming the recessed surface 360a, may, in one embodiment, be performed in situ on a single CMP unit 100 or, in other embodiments, on different CMP units, for example, of the CMP system 200. Preferably, an in situ process may be employed when only the down force and/or the relative speed are altered. Different CMP units may be employed when the polishing pads 102 in both CMP processes require different characteristics.

FIG. 3d depicts the damascene structure 300 after a barrier removal process. Although less pronounced, the upper surface 360a of the metal region 356b is still significantly recessed and portions of the sidewalls 370a of the opening are exposed. The sidewalls 370a may be covered by the barrier layer 358a. In one embodiment, the surface is recessed by approximately 2-50 nm. Since the barrier removal process is performed after recessing the surface 360a of the metal region 356b, dishing that occurs in conventional barrier removal processes may be avoided or at least reduced. The barrier polish may be performed by well known barrier polish processes, for example, in situ on the CMP unit 100 employed for the recess forming CMP process. In a further embodiment, the barrier polish process may be performed on the CMP unit 230 of the CMP system 200 after the substrate 307 is conveyed from the unit 225 to the unit 230.

It is to be noted that the CMP barrier removal process may jeopardize the underlying dielectric, in particular when “soft” low-k materials are employed. To overcome that problem, typically a thin layer of a harder materiel providing the required stability may be deposited on the dielectric layer 354 prior to forming the opening for the metal region 356.

FIG. 3e depicts the damascene structure 300 after an upper barrier cap layer 362 is deposited. The cap layer 362 may be formed by CVD or other appropriate techniques, wherein respective cleaning processes may be performed prior to the formation of the cap layer 362, especially if the metal-containing region 356b is comprised of copper or copper-based alloys, since the surface 360a readily reacts with the ambient or any reactive components that are still left on the surface 360a after the CMP recess process. Even during the CMP process for forming the recessed surface 360a, the metal surface may react with reactive ingredients of the CMP and/or the etch process, or may simply oxidize upon contact with the ambient atmosphere during the CMP process. Especially copper tends to form discoloration and corrosion on the exposed surface 360a, which therefore requires a clean process for substantially removing any undesired discolored and/or oxidized portions. Typically, the deposition process for forming the cap layer 362 is combined with a preceding clean process so that the cleaned surface 360a may immediately be covered by the cap layer 362, thereby passivating the surface 360a and reducing or preventing the re-formation of oxidized portions during further manufacturing steps.

The cap layer 362 may be comprised of an appropriate material that, in the first place, effectively suppresses the diffusion of the metal of the metal region 356b into adjacent device regions, for instance further metallization layers that are still to be formed on top of the cap layer 362. Moreover, the cap layer 362 may additionally act as an etch stop layer in a subsequent patterning process for forming vias connecting to overlying metallization layers still to be formed. The cap layer 362 may be comprised of two or more sub-layers to meet the various requirements with respect to the diffusion blocking capability and etch selectivity, and the like. In some embodiments, the cap layer 362 may substantially be comprised of silicon nitride that exhibits an excellent diffusion mitigating effect with respect to a plurality of materials, including copper and copper-based alloys. Moreover, etch recipes exhibiting a moderate selectivity with respect to silicon dioxide are well-known and well-established in the art so that silicon nitride is frequently used in combination with silicon dioxide for the formation of metallization layers. In other cases, when the permittivity of the dielectric separating the individual metal lines and metal regions are of relevance, materials on the basis of silicon carbide may be used for forming the cap layer 362. In some embodiments, the provision of a different material composition along the depth direction of the cap layer 362 may be considered appropriate or the material composition may be varied to obtain different characteristics at an interface 364 with surface 360a compared to the upper surface of the cap layer 362. A thickness of the cap layer 362 may depend on the characteristics, i.e., on the material composition and/or the formation technique for forming the cap layer 362, and may range in some embodiments between approximately 10-70 nm.

Due to the recessed surface 360a, the cap layer 362 deposited on the metal region 356b is “inlaid” in the dielectric layer 354 so that the mechanical stability of the interface 364 between the metal region 356b and the cap layer 362 is improved compared to conventional deposition on non-recessed surfaces, while concurrently contrary to an etched recess, the interface 364 between the metal region 356b and the cap layer 362 is more smooth so that the electromigration characteristic at the interface 364 may be improved.

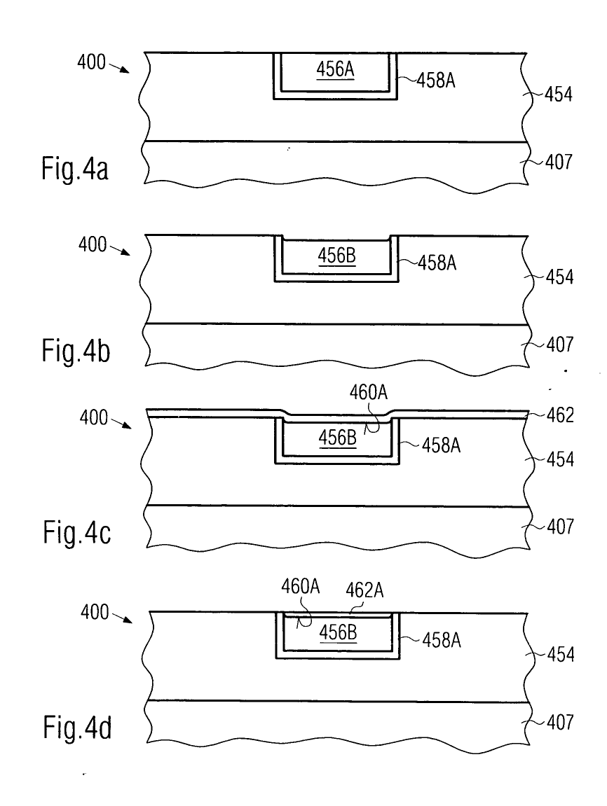

FIGS. 4a-4d illustrate further embodiments according to the present invention for forming a damascene structure 400, wherein the barrier removal process is performed prior to the recess forming CMP process.

FIG. 4a shows a damascene structure 400, including a substrate 407, a dielectric layer 454, a metal region 456a and a barrier layer 458a, after a barrier removal CMP process is performed to a structure as depicted in FIG. 3b. The CMP barrier removal process may be carried out as described with respect to the barrier removal process of FIG. 3d.

FIG. 4b depicts the damascene structure 400 after performing a recess forming CMP process. The corresponding CMP process may be carried out as described with respect to FIG. 3c. Contrary thereto, the barrier layer may not act as a CMP stop layer so that during the recess forming process also dielectric material from the layer 454 may be removed. Thus, the thickness of the dielectric layer 454 as deposited may, if required, accordingly be increased. That applies, in particular, for low-k materials and any capping layers deposited to stabilize the low-k layer, as described with respect to FIG. 3d. The exposed corners of the opening of the structure 400 may be more rounded than the corresponding corners of the structure 300 since the rounded corners of structure 300 are removed in the barrier removal step.

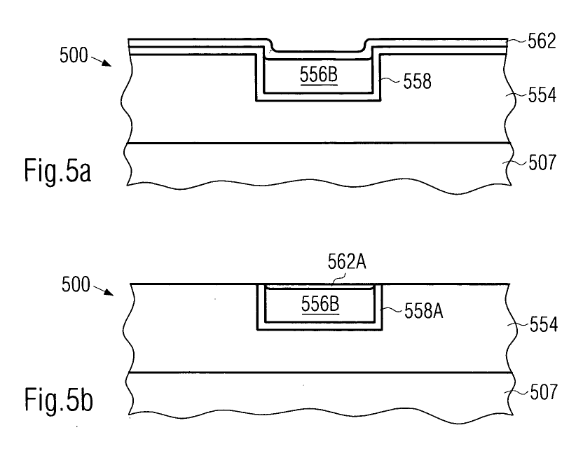

FIG. 4c depicts the damascene structure 400 after depositing a barrier cap layer 462. In applications for high speed devices, for example, state of the art microprocessors, the permittivity of the barrier cap layer may unacceptably increase the overall permittivity of the layer stack formed by the dielectric layer 454 and the cap layer 462. Since the cap layer 462 is deposited on a recessed surface 460a of the metal region 456b, the cap layer 462 may be removed from the dielectric layer 454 by a CMP process so that the overall permittivity is reduced, while still maintaining a reliable barrier and etch stop layer 462a on the metal region 456b as depicted in FIG. 4d. A similar damascene structure may be achieved by subjecting the structure depicted in FIG. 3e to a corresponding CMP process. The CMP process planarizes the upper surface of the structure, thus, further processing of the substrate 407, for example, in a subsequent photolithography process, may be facilitated. Since the barrier cap layer 462a, after the barrier polishing process, covers only the metal region 456b, the barrier cap layer 462a may comprise a conductive material, such as tantalum and/or tantalum nitride or the like. Corresponding barrier layer CMP processes, for instance, for silicon nitride or tantalum/tantalum nitride polishing are well known. A further manufacturing process resulting in a similar damascene structure and without the additional barrier layer CMP process is set forth in the following with respect to FIGS. 5a and 5b.

FIG. 5a schematically shows a damascene structure 500 that may be formed by depositing a barrier cap layer 562 on a structure, as shown in FIG. 3c. Thus the structure 500 further comprises a substrate 507, a dielectric layer 554, a barrier layer 558 and a metal region 556b. The barrier cap layer 562 may comprise, as set forth before, a dielectric or a conductive material, exhibiting the required barrier behavior and etch selectivity, e.g., silicon nitride, silicon carbide, tantalum and/or tantalum nitride. In one specific embodiment, the barrier cap layer 562 comprises the same material as the barrier layer 558 so that both the barrier layer 558, and the layer 562 may readily be removed in a common CMP process.

FIG. 5b schematically shows a damascene structure 500 after a barrier removal CMP process forming barrier layers 558a, 562a encapsulating the metal region 556b. For a copper interconnect line, both barrier layers 558a, 562a may, for example, comprise tantalum and/or tantalum nitride. Thus, the barrier cap layer 562a may also contribute to the conductivity of the interconnect line. If the etch selectivity of a conductive cap barrier layer 562a is insufficient, the barrier cap layer 562a may at least serve as an etch indicator layer to reliably control a dry etch process by analyzing the atmosphere in the etch chamber to generate an etch stop signal when the concentration of the barrier material in the atmosphere is substantially increased.

As a result, the present invention provides a technique that enables the formation of a recessed upper surface of an interconnect line to form an inlaid barrier cap layer on top of an interconnect line to exhibit improved characteristics with respect to electromigration, electrical conductivity, device reliability and performance. The recessed upper surface of the inter-connect line is formed by an accordingly adapted CMP process that allows removing the metal of an upper portion of the interconnect line, while neighboring elevated barrier layer regions are substantially not affected.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a dielectric layer above a substrate;
forming a metal region in said dielectric layer, said metal region having an exposed surface;
adjusting chemical mechanical polishing process parameters for polishing of said exposed surface; and
performing chemical mechanical polishing on said exposed surface with said parameters to intentionally form a recessed surface of said metal region.

2. The method of claim 1, further comprising forming a barrier cap layer on said recessed surface.

3. The method of claim 2, wherein said barrier layer and said barrier cap layer comprise the same material.

4. The method of claim 3, wherein said barrier layer and said barrier cap layer are chemically mechanically polished in a common polishing process.

5. The method of claim 1, wherein said metal region comprises copper.

6. The method of claim 1, wherein forming a metal region in said dielectric layer comprises:
forming an opening in said dielectric layer;
depositing a metal layer on said dielectric layer and in said opening by a plating process; and
performing a chemical mechanical polishing process to remove excess metal from said dielectric layer.

7. The method of claim 6, further comprising:
depositing a barrier layer prior to depositing said metal layer; and
removing partially said barrier layer.

8. The method of claim 7, wherein said barrier layer and said barrier cap layer comprise the same material.

9. The method of claim 8, wherein said barrier layer and said barrier cap layer are chemically mechanically polished in a common polishing process.

10. The method of claim 7, wherein said chemical mechanical polishing of said exposed surface is performed after performing chemical mechanical polishing to remove excess metal from said dielectric layer.

11. The method of claim 10, wherein, in said chemical mechanical polishing process of said exposed surface, at least one of an amount of a complexing agent and a down force is increased with respect to the CMP for excess metal removal.

12. The method of claim 11, wherein said amount of said complexing agent is increased by a factor of approximately 2 to 10.

13. The method of claim 11, wherein said amount of said complexing agent is increased by a factor of approximately 4.

14. The method of claim 11, wherein said down force is in a range of approximately 5 to 7 psi.

15. The method of claim 10, wherein, in said chemical mechanical polishing process of said exposed surface, a relative speed between said substrate and a polishing pad is reduced with respect to the CMP for excess metal removal.

16. The method of claim 15, wherein said relative speed between said substrate and said polishing pad is less than approximately 50 m/min.

17. The method of claim 10, wherein a hardness of said polishing pad is reduced with respect to the CMP for excess metal removal.

18. The method of claim 15, wherein said polishing pad is embossed.

19. The method of claim 10, wherein said chemical mechanical polishing process of said exposed surface is performed in situ with said CMP for excess metal removal process.

20. The method of claim 1, wherein a polishing time of said chemical mechanical polishing process of said exposed surface is in a range of approximately 10-30 seconds.

21. The method of claim 7, wherein said chemical mechanical polishing process of said exposed surface is performed after removing said barrier layer.

22. The method of claim 21, wherein said chemical mechanical polishing process of said exposed surface is performed in situ with said CMP barrier layer removal process.

23. A damascene structure comprising:
a dielectric layer formed above a substrate;
a metal region formed in said dielectric layer; and
an electrically conductive barrier cap region formed above said metal region.

24. The damascene structure of claim 23, wherein said metal region comprises copper.

25. The damascene structure of claim 24, wherein the material of said barrier cap region is comprised of at least one of tantalum, tantalum nitride, titanium and titanium nitride.

26. The damascene structure of claim 23, wherein a thickness of said barrier cap region is in a range of approximately 5-50 nm.

27. A damascene structure comprising:
a dielectric layer formed above a substrate;
a metal region formed in said dielectric layer; and
a barrier cap region located above said metal region in said dielectric layer.

28. The damascene structure of claim 27, wherein said metal region comprises copper.

29. The damascene structure of claim 27, wherein a material of said barrier cap region is comprised of a material different from the material of said dielectric layer.

30. The damascene structure of claim 29, wherein the material of said barrier cap region is comprised of at least one of silicon nitride and silicon carbide.

31. The damascene structure of claim 27, wherein said barrier cap region is laterally in contact with said dielectric layer.
